(19) United States
(12) Patent Application Publication
(10) Pub. No.: US 2024/0347573 A1
(43) Pub. Date: Oct. 17, 2024

(54) APPARATUS

(71) Applicant: CANON KABUSHIKI KAISHA, Tokyo (JP)

(72) Inventors: DAIKI SHIRAHIGE, Kanagawa (JP); HIROSHI SEKINE, Kanagawa (JP)

(21) Appl. No.: 18/612,936

(22) Filed: Mar. 21, 2024

(30) Foreign Application Priority Data
Mar. 28, 2023 (JP) 2023-051698

(51) Int. Cl. H01L 27/146

(52) U.S. Cl. CPC H01L 27/14636; H01L 27/14607; H01L 27/14627; H01L 27/14643

(57) ABSTRACT

An apparatus includes a plurality of pixels, a layer that has a first surface and a second surface opposite the first surface and that includes a plurality of photodiodes, a wiring layer that is disposed on a first surface side and that includes first wiring and second wiring. Each of the plurality of pixels includes a first photodiode, a second photodiode located adjacent to the first photodiode in a first direction, and a microlens disposed on the second surface side so as to be common to the first photodiode and the second photodiode, and a width of the first wiring disposed between the second wiring of the first photodiode and the second wiring of the second photodiode is greater than a width of the first wiring disposed between the plurality of pixels in the first direction.

### BACKGROUND

### Technical Field

The aspect of the embodiments relates to a photoelectric conversion apparatus.

### Description of the Related Art

Photoelectric conversion apparatuses including avalanche photodiodes (APDs) have been developed.

Japanese Patent Laid-Open No. 2020-141122 describes a configuration that enables phase difference detection by placing one microlens on a plurality of pixels including APDs. In addition, Japanese Patent Laid-Open No. 2018-088488 describes a configuration in which a reflective structure with metal wiring is provided on a plurality of pixels including APDs to improve the sensitivity.

In the configuration described in Japanese Patent Laid-Open No. 2020-141122, light penetrates into a wiring layer and, thus, the sensitivity may be decreased and crosstalk may occur. In addition, if the configuration described in Japanese Patent Laid-Open No. 2018-088488 is applied to a photoelectric conversion apparatus with one microlens disposed on a plurality of APDs, the location of metal wiring relative to the light focusing position is not optimal as compared with the configuration in which one microlens is disposed on one APD. This may result in a decrease in sensitivity and an increase in crosstalk.

### SUMMARY

According to an aspect of the embodiments, an apparatus includes a plurality of pixels, a layer having a first surface and a second surface opposite the first surface, wherein the layer includes a plurality of photodiodes, and a wiring layer disposed on a first surface side, wherein the wiring layer includes first wiring and second wiring, wherein each of the plurality of pixels includes a first photodiode, a second photodiode located adjacent to the first photodiode in a first direction, and a microlens disposed on the second surface side so as to be common to the first photodiode and the second photodiode, and wherein a width of the first wiring disposed between the second wiring of the first photodiode and the second wiring of the second photodiode is greater than a width of the first wiring disposed between the plurality of pixels in the first direction.

According to another aspect of the embodiments, an apparatus includes a plurality of pixels, a layer having a first surface and a second surface opposite the first surface, wherein the layer includes a plurality of photodiodes, and a wiring layer disposed on a first surface side, wherein the wiring layer includes first wiring and second wiring, wherein each of the plurality of pixels includes a first photodiode, a second photodiode located adjacent to the first photodiode in a first direction, and a microlens disposed on the second surface side so as to be common to the first photodiode and the second photodiode, and wherein the first wiring is not provided between the second wiring of the first photodiode and the second wiring of the second photodiode in the first direction.

Further features of the disclosure will become apparent from the following description of exemplary embodiments with reference to the attached drawings.

### BRIEF DESCRIPTION OF THE DRAWINGS

FIG. 1 is a schematic illustration of a photoelectric conversion apparatus.

FIG. 2 is a schematic illustration of a pixel array.

FIG. 3 is a configuration diagram of a circuit substrate.

FIG. 4 is an equivalent circuit diagram of a pixel.

FIGS. 5A and 5B and 5C illustrate the operation performed by an SPAD pixel.

FIG. 6 illustrates a comparative example of a cross-sectional view of pixels.

FIG. 7 illustrates a comparative example of a plan view of pixels.

FIG. 8 is a plan view of pixels of a photoelectric conversion apparatus according to a first embodiment.

FIG. 9 is a cross-sectional view of the pixel of the photoelectric conversion apparatus according to the first embodiment.

FIG. 10 is a cross-sectional view of pixels of the photoelectric conversion apparatus according to the first embodiment.

FIG. 11 is a plan view of pixels of a photoelectric conversion apparatus according to a second embodiment.

FIG. 12 is a cross-sectional view of the pixels of the photoelectric conversion apparatus according to the second embodiment.

FIG. 13 is a plan view of pixels of a photoelectric conversion apparatus according to a third embodiment.

FIG. 14 is a plan view of pixels of a photoelectric conversion apparatus according to a fourth embodiment.

FIG. 15 is a cross-sectional view of the pixels of the photoelectric conversion apparatus according to the fourth embodiment.

FIG. 16 is a plan view of pixels of a photoelectric conversion apparatus according to a fifth embodiment.

FIG. 17 is a cross-sectional view of the pixels of the photoelectric conversion apparatus according to the fifth embodiment.

FIG. 18 is a plan view of pixels of a photoelectric conversion apparatus according to a sixth embodiment.

FIG. 19 is a cross-sectional view of the pixels of the photoelectric conversion apparatus according to the sixth embodiment.

FIG. 20 is a functional block diagram of a photoelectric conversion system according to a seventh embodiment.

FIGS. 21A and 21B are functional block diagrams of a photoelectric conversion system according to an eighth embodiment.

FIG. 22 is a functional block diagram of a photoelectric conversion system according to a ninth embodiment.

FIG. 23 is a functional block diagram of a photoelectric conversion system according to a tenth embodiment.

FIGS. 24A and 24B illustrate a photoelectric conversion system according to an eleventh embodiment.

### DESCRIPTION OF THE EMBODIMENTS

Embodiments described below are for embodying the technical concept of the present disclosure and are not intended to limit the present disclosure. The sizes and positional relationships of members illustrated in the drawings may be exaggerated for clarity of description. In the following description, the same configuration may be identified by the same reference numeral, and description may be omitted.

The embodiments of the present disclosure are described in detail below with reference to the accompanying drawings. In the following description, the terms indicating specific directions and positions (for example, “upper”, “lower”, “right”, “left”, and other terms including these terms) are used as necessary. These terms are used to facilitate understanding of the embodiments with reference to the drawings, and the technical scope of the present disclosure is not limited by the meanings of the terms.

In the following description, the anode of an avalanche photodiode (APD) is set at a fixed electric potential, and a signal is taken from the cathode side. Therefore, a semiconductor region of a first conductivity type in which the charges of a polarity the same as that of a signal charge are majority carriers is an N-type semiconductor region, and a semiconductor region of a second conductivity type in which the charges of the polarity different from that of a signal charge are majority carriers is a P-type semiconductor region.

The present disclosure can also be applied when the cathode of the APD is set at a fixed electric potential and the signal is taken from the anode side. In this case, the semiconductor region of the first conductivity type in which charges of a polarity the same as that of the signal charge are majority carriers is a P-type semiconductor region, and the semiconductor region of the second conductivity type in which charges of a polarity different from that of the signal charge are majority carriers is an N-type semiconductor region. Hereinafter, the case where one of the nodes of the APD is set to a fixed electric potential is described below. However, the potentials of both nodes may vary.

The term “impurity concentration” as simply used herein refers to the net impurity concentration obtained after subtracting the amount compensated by the impurity of an opposite conductivity type. That is, the term “impurity concentration” refers to the NET doping concentration. A region in which the P-type additive impurity concentration is higher than the N-type additive impurity concentration is a P-type semiconductor region. In contrast, a region in which the N-type additive impurity concentration is higher than the P-type additive impurity concentration is an N-type semiconductor region.

As used herein, the term “plan view” is used to refer to a view in a direction perpendicular to the surface opposite the light incident surface of a semiconductor layer (described below). The term “cross section” refers to a plane extending in a direction perpendicular to the surface opposite the light incident surface of the semiconductor layer. When the light incident surface of the semiconductor layer is microscopically rough, the plan view is defined on the basis of the light incident surface of the semiconductor layer when viewed macroscopically.

A semiconductor layer 300 (described below) has a first surface and a second surface that is opposite the first surface, and light is incident on the second surface. As used herein, the term “depth direction” refers to a direction from the first surface having an APD disposed thereon to the second surface of the semiconductor layer 300. Hereinafter, the first surface is also referred to as a “front side”, and the second surface is also referred to as a “back side”. The direction from a predetermined position of the semiconductor layer 300 to the back side of the semiconductor layer 300 is also referred to as a “deep” direction. Furthermore, the direction from a predetermined position of the semiconductor layer 300 toward the front side of the semiconductor layer 300 is also referred to as a “shallow” direction.

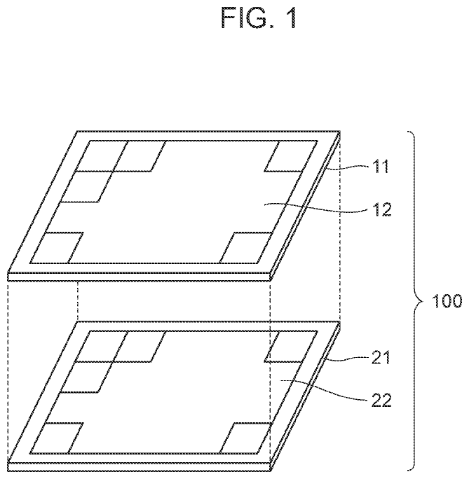

A configuration common to all embodiments is described first with reference to FIGS. 1 to 4 and FIGS. 5A and 5B.

FIG. 1 illustrates the configuration of a stacked photoelectric conversion apparatus 100. The photoelectric conversion apparatus 100 is configured by stacking and electrically connecting a sensor substrate 11 with a circuit substrate 21. The sensor substrate 11 has a first semiconductor layer (a semiconductor layer 300) including photoelectric conversion elements 102 (described below) and a first wiring structure. The circuit substrate 21 has a second semiconductor layer including circuits, such as a signal processing unit 103 (described below), and a second wiring structure. The photoelectric conversion apparatus 100 is configured by stacking the second semiconductor layer, the second wiring structure, the first wiring structure, and the first semiconductor layer in this order. The photoelectric conversion apparatus described in each of the embodiments is a back-illuminated photoelectric conversion apparatus in which light is incident on the second surface and a circuit substrate is disposed on the first surface.

Although the sensor substrate 11 and the circuit substrate 21 in the form of diced chips are described below, the forms are not limited to chips. For example, the substrates may be wafers. In addition, the substrates in the form of wafers may be stacked and then diced or may be made into chips from a wafer and then stacked and bonded.

The sensor substrate 11 has a pixel region 12 disposed therein, and the circuit substrate 21 has, disposed therein, a circuit region 22 for processing signals detected by the pixel region 12.

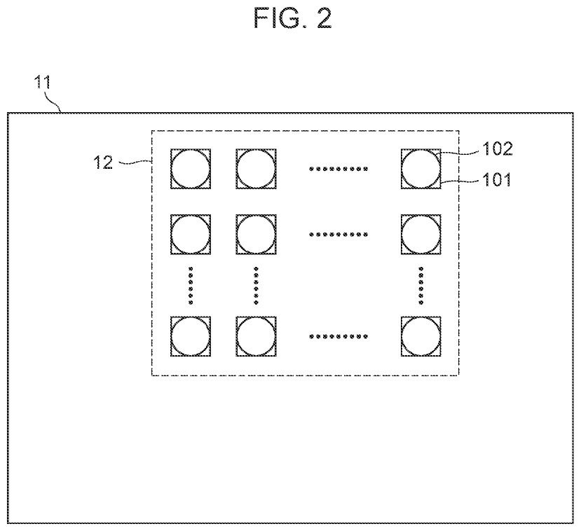

FIG. 2 illustrates an arrangement example in the sensor substrate 11. Pixels 101 each having a photoelectric conversion element 102 including an APD are arranged in a two-dimensional array in plan view to form the pixel region 12.

The pixels 101 are typically pixels for forming an image. However, when used for TOF (Time of Flight), the pixels 101 do not necessarily form an image. That is, the pixels 101 may be provided to measure the time and the amount of light when the light reaches the pixels 101.

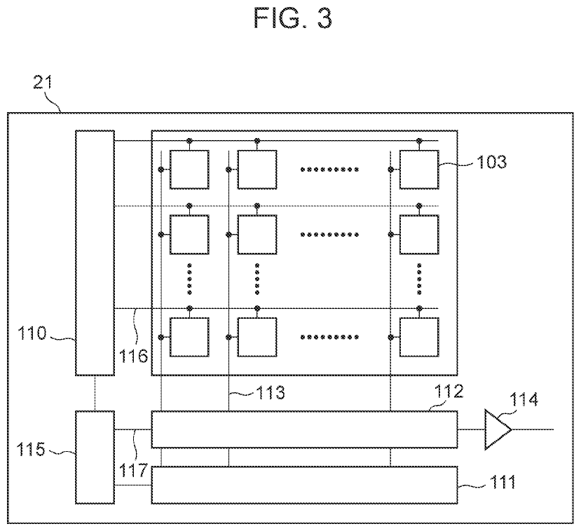

FIG. 3 is a configuration diagram of the circuit substrate 21. The circuit substrate 21 includes the signal processing units 103 that process charges photoelectrically converted by the photoelectric conversion elements 102 illustrated in FIG. 2, a readout circuit 112, a control pulse generation circuit 115, a horizontal scanning circuit unit 111, a signal lines 113, and a vertical scanning circuit unit 110.

The photoelectric conversion element 102 illustrated in FIG. 2 and the signal processing unit 103 illustrated in FIG. 3 are electrically connected via a connection conductive line provided for each of the pixels.

The vertical scanning circuit unit 110 receives a control pulse supplied from the control pulse generation unit 115 and supplies the control pulse to each of the pixels. Logic circuits, such as a shift register and an address decoder, are used in the vertical scanning circuit unit 110.

A signal output from the photoelectric conversion element 102 of the pixel is processed by the signal processing unit 103. The signal processing unit 103 includes a counter, a memory, and the like, and a digital value is held in the memory.

The horizontal scanning circuit unit 111 inputs a control pulse for sequentially selecting each of columns to the signal processing unit 103 to read a signal from the memory of each of the pixels that holds the digital signal.

The signal is output to the signal line 113 from the signal processing unit 103 of the pixel selected by the vertical scanning circuit unit 110 for the selected column.

The signal output to the signal line 113 is output to an external recording unit or the signal processing unit of the photoelectric conversion apparatus 100 via an output circuit 114.

In FIG. 2, the array of photoelectric conversion elements in the pixel region may be a one-dimensional array. The function of the signal processing unit does not necessarily have to be provided for each of the photoelectric conversion elements. For example, one signal processing unit may be shared by a plurality of photoelectric conversion elements, and signal processing may be performed sequentially.

As illustrated in FIGS. 2 and 3, a plurality of signal processing units 103 are arranged in a region that overlaps the pixel region 12 in plan view. The vertical scanning circuit unit 110, the horizontal scanning circuit unit 111, the readout circuit 112, the output circuit 114, and the control pulse generation unit 115 are arranged so as to overlap a region between the edges of the sensor substrate 11 and the edges of the pixel region 12 in plan view. That is, the sensor substrate 11 has the pixel region 12 and a non-pixel region disposed surrounding the pixel region 12, and the vertical scanning circuit unit 110, the horizontal scanning circuit unit 111, the readout circuit 112, the output circuit 114, and the control pulse generation unit 115 are disposed in regions that overlap the non-pixel region in plan view.

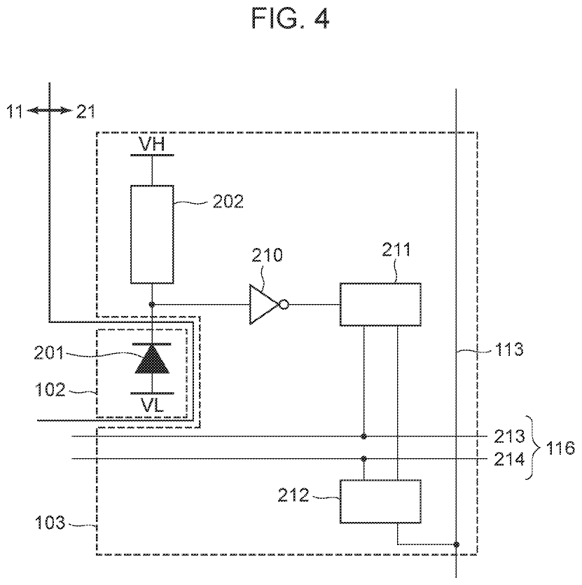

FIG. 4 is an example of a block diagram including the configuration illustrated in FIG. 2 and the equivalent circuit illustrated in FIG. 3.

In FIG. 2, the photoelectric conversion element 102 including an APD 201 is provided in the sensor substrate 11, and the other members are provided in the circuit substrate 21.

The APD 201 generates charge pairs in accordance with incident light by photoelectric conversion. A voltage VL (a first voltage) is supplied to the anode of the APD 201. In addition, a voltage VH (a second voltage) that is higher than the voltage VL supplied to the anode is supplied to the cathode of the APD 201. A reverse bias voltage is supplied to the anode and cathode so that the APD 201 performs an avalanche multiplication operation. By supplying such voltages, charges generated by the incident light undergo avalanche multiplication, which generates an avalanche current.

When a reverse bias voltage is supplied, an APD has two modes of operation: the Geiger mode in which the potential difference between the anode and cathode is greater than the breakdown voltage and the linear mode in which the potential difference between the anode and cathode is less than or equal to the breakdown voltage.

An APD operated in the Geiger mode is referred to as an SPAD (single photon avalanche diode). For example, the voltage VL (the first voltage) is −30 V, and the voltage VH (the second voltage) is 1 V. The APD 201 may be operated in either the linear mode or the Geiger mode.

A quenching element 202 is connected to a power source that supplies the voltage VH and the APD 201. The quenching element 202 functions as a load circuit (a quenching circuit) during signal multiplication by avalanche multiplication, reduces the voltage supplied to the APD 201, and has a function of reducing avalanche multiplication (a quenching operation). In addition, the quenching element 202 has a function of causing a current corresponding to the voltage drop due to the quenching operation to flow and returning the voltage supplied to the APD 201 to the voltage VH (a recharge operation).

The signal processing unit 103 includes a waveform shaping unit 210, a counter circuit 211, and a selection circuit 212. Herein, the signal processing unit 103 can include any one of the waveform shaping unit 210, the counter circuit 211, and the selection circuit 212.

The waveform shaping unit 210 shapes a change in the potential of the cathode of the APD 201 obtained during photon detection and outputs a pulse signal. For example, an inverter circuit is used as the waveform shaping unit 210. Although FIG. 4 illustrates an example in which one inverter is used as the waveform shaping unit 210, a circuit in which a plurality of inverters are connected in series may be used, or another circuit having a waveform shaping effect may be used.

The counter circuit 211 counts the pulse signals output from the waveform shaping unit 210 and holds a count value. Furthermore, when a control pulse pRES is supplied via a drive line 213, a count value held in the counter circuit 211 is reset.

The selection circuit 212 is supplied with a control pulse pSEL from the vertical scanning circuit unit 110 illustrated in FIG. 3 via a drive line 214 illustrated in FIG. 4 (not illustrated in FIG. 3) and switches between connection and disconnection of the counter circuit 211 from the signal line 113. The selection circuit 212 includes, for example, a buffer circuit for outputting a signal.

A switch, such as a transistor, may be provided between the quenching element 202 and the APD 201 or between the photoelectric conversion element 102 and the signal processing unit 103 to switch the electrical connection. Similarly, the voltage VH and the voltage VL supplied to the photoelectric conversion element 102 may be electrically switched using a switch, such as a transistor.

According to the present embodiment, the configuration using the counter circuit 211 is described. However, the photoelectric conversion apparatus 100 that acquires the pulse detection timing may be achieved by using a time-to-digital converter (hereinafter referred to as a TDC) and a memory instead of the counter circuit 211. At this time, the generation timing of the pulse signal output from the waveform shaping unit 210 is converted into a digital signal by the TDC. To measure the timing of the pulse signal, the TDC receives a control pulse pREF (a reference signal) supplied thereto from the vertical scanning circuit unit 110 illustrated in FIG. 3 via the drive line. The TDC acquires a signal in the form of a digital signal when the input timing of the signal output from each of the pixels via the waveform shaping unit 210 is regarded as a time relative to the control pulse PREF.

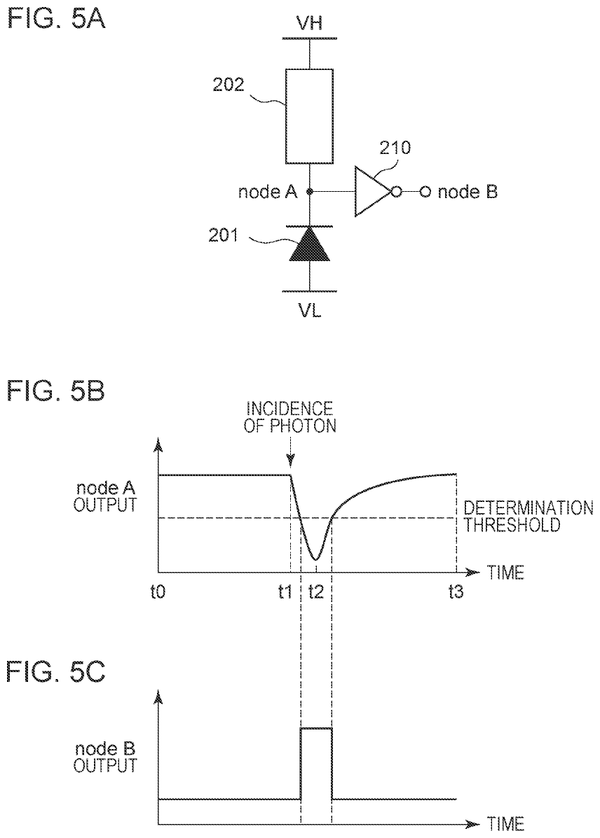

FIGS. 5A to 5C are schematic illustrations of the relationship between the operation performed by the APD and the output signals.

FIG. 5A illustrates the APD 201, the quenching element 202, and the waveform shaping unit 210 illustrated in FIG. 4. In FIG. 5A, let node A be the input side of the waveform shaping unit 210, and let node B be the output side of the waveform shaping unit 210. Then, FIG. 5B illustrates a change in the waveform in the node A illustrated in FIG. 5A, and FIG. 5C illustrates a change in the waveform in the node B illustrated in FIG. 5A.

Between time t0 and time t1, a potential difference of (VH−VL) is applied to the APD 201 illustrated in FIG. 5A. When a photon is incident on the APD 201 at time t1, avalanche multiplication occurs in the APD 201, an avalanche multiplication current flows through the quenching element 202, and the voltage in the node A drops. When the voltage drop amount further increases and the potential difference applied to the APD 201 decreases, the avalanche multiplication in the APD 201 stops at time t2, and the voltage level of the node A does not drop beyond a certain value. Thereafter, between time t2 to time t3, a current that compensates for the voltage drop from the voltage VL flows through the node A. After time t3, the node A remains at the original potential level. At this time, a portion of the output waveform in the node A exceeding a certain threshold is shaped by the waveform shaping unit 210 and is output as a signal in the node B.

It should be noted that the arrangement of the signal lines 113 and the arrangement of the readout circuit 112 and the output circuit 114 are not limited to those illustrated in FIG. 3. For example, the signal lines 113 may be arranged extending in the row direction, and the readout circuit 112 may be disposed at the end of the signal line 113 in the extending direction.

A photoelectric conversion apparatus according to each of the embodiments is described below.

### First Embodiment

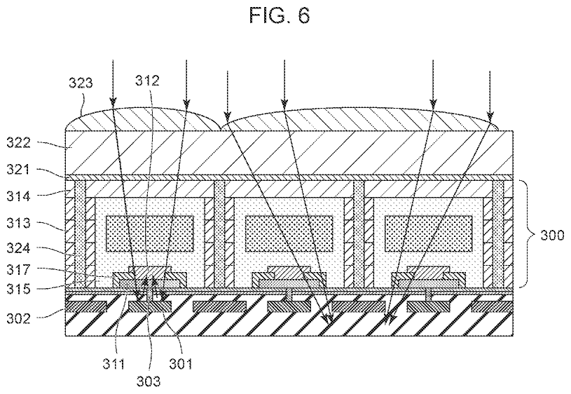

A photoelectric conversion apparatus according to the first embodiment is described below with reference to FIGS. 6 to 11.

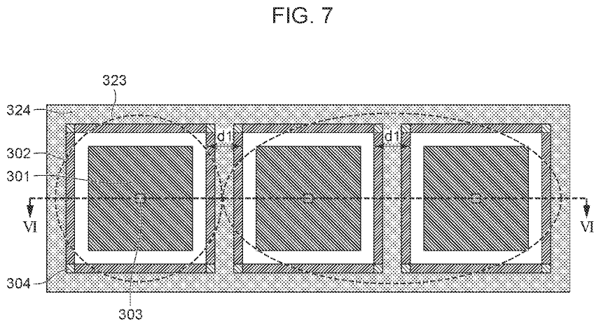

FIGS. 6 and 7 illustrate a comparative example of a photoelectric conversion apparatuses having pixels with a reflective metal structure using cathode wiring 301 and anode wiring 302. The left pixel in FIG. 6 has one microlens 323 for one APD, while the right pixel illustrated in FIG. 6 has two APDs that share one microlens 323. That is, in the right pixel illustrated in FIG. 6, the microlens 323 is disposed so as to be common to a first avalanche photodiodes and a second avalanche photodiode.

As illustrated in FIG. 6, the photoelectric conversion apparatus according to the present comparative example is a back-illuminated photoelectric conversion apparatus, and a wiring layer in which wiring, such as the cathode wiring 301 and the anode wiring 302, is disposed is located on the front side of the semiconductor layer 300. The cathode wiring 301 is the wiring that supplies a voltage to one terminal (a cathode terminal) of the APD, and the anode wiring 302 is the wiring that supplies a voltage to the other terminal (an anode terminal) of the APD. FIG. 7 illustrates the wiring positional relationship as viewed in plan view from the back side.

FIG. 7 does not necessarily illustrate only structures that are located in the same plane. In the photoelectric conversion apparatus according to the comparative example, both one APD disposed under one microlens 323 and two APDs that share one microlens 323 include the cathode wiring 301 and the anode wiring 302 each being symmetrical about a cathode contact 303. A distance d1 between the anode wirings 302 of the APDs is constant regardless of whether the microlens 323 is shared or not.

The effect of the reflective metal structure on improvement of the sensitivity of the photoelectric conversion apparatus is described below with reference to the left pixel illustrated in FIG. 6. Light that penetrates into the semiconductor layer 300 is photoelectrically converted in the semiconductor layer 300. Part of the incident light is not photoelectrically converted, reaches the wiring layer, is reflected by the cathode wiring 301 and anode wiring 302 disposed in the wiring layer, and returns to the semiconductor layer 300. The reflection causes the light that originally passes through the wiring layer and is not photoelectrically converted to be photoelectrically converted in the semiconductor layer 300. That is, the sensitivity of the photoelectric conversion apparatus can be improved by providing the reflective metal structure. In particular, because the longer wavelength light, which is difficult to be photoelectrically converted, tends to penetrate deeper into the semiconductor layer 300, the reflective metal structure has a greater effect on improving sensitivity.

As illustrated in the right pixel in FIG. 6, in the configuration in which one microlens 323 is shared by a plurality of APDs, the position at which incident light is focused by the microlens 323 is shifted from the center position of each of the APDs. For example, in the configuration illustrated in FIG. 6, the light is focused on a region between the APDs that share a microlens. Therefore, if an existing pixel structure is employed, the light passes through the wiring layer without being reflected by the metal wiring in the wiring layer and, thus, the effect of sensitivity improvement by a reflective metal is not sufficient.

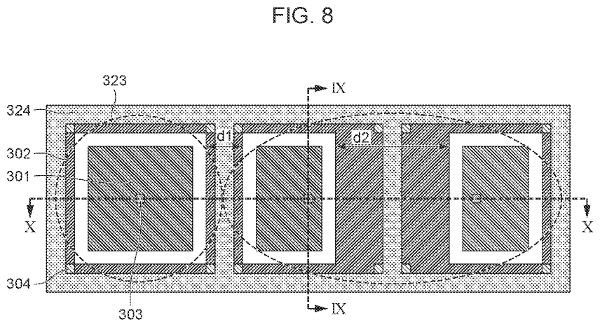

The plan view structure of the photoelectric conversion apparatus according to the present embodiment is described below with reference to FIG. 8. FIG. 8 is a schematic plan view of a pixel including two APDs among a plurality of pixels included in the pixel region 12 and illustrates each of the structures necessary to describe the positional relationship in plan view from the back side. Therefore, FIG. 8 does not necessarily illustrate only structures that are located in the same plane.

For example, since the anode wiring 302 overlaps a separation layer 324 as viewed in plan view from the back side of the semiconductor layer 300, the separation layer 324 is illustrated in the foreground in plan view. The anode wiring 302 is also continuously disposed at a region overlapping the separation layer 324 as viewed in plan view from the back side and has a mesh shaped configuration. In FIG. 8, to describe the arrangement of the cathode wiring 301 and the anode wiring 302 in particular, some other structures are not illustrated.

As illustrated in FIG. 8, each of the pixels 101 includes at least one APD. In the present example, the configuration including two APDs is illustrated. In addition, the separation layer 324 is disposed between the pixels or between the APDs. Hereinafter, a configuration in which the pixel 101 is composed of two APDs is described. However, the number of APDs included in the pixel 101 is not limited thereto.

The microlens 323 is disposed on the light incident side of the pixel. FIG. 8 illustrates an example in which the microlens 323 is disposed above two APDs arranged in one row x two columns. According to the configuration in which a microlens is shared by a plurality of APDs, a light flux that has passed through a certain region of the objective lens is captured by each of the APDs, and the amount and direction of defocusing can be detected from the difference between the outputs of the APD groups under the microlens 323. This configuration provides image plane phase-difference detection autofocus, which enables both image capturing and phase detection.

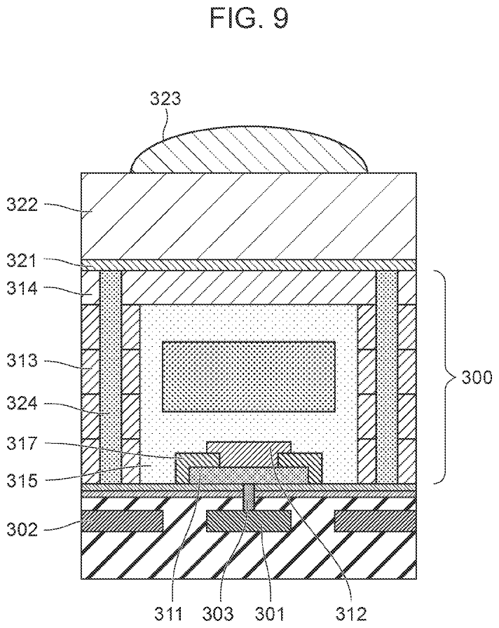

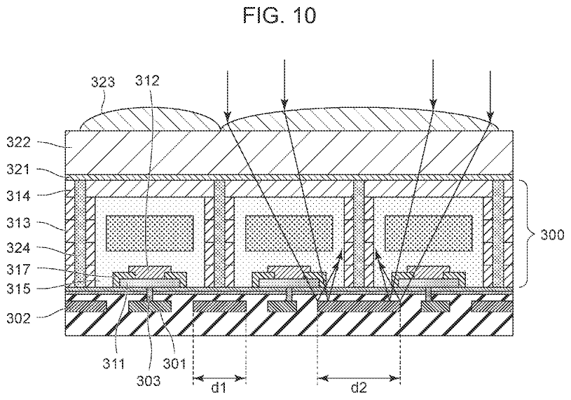

Each of the semiconductor regions disposed in the semiconductor layer 300 is described below with reference to FIGS. 9 and 10 that illustrate the cross sections taken along line IX-IX and X-X illustrated in FIG. 8. FIG. 9 is a schematic cross-sectional view taken along line IX-IX and illustrates a pinning film 321, a planarization layer 322, and the microlens 323 formed on the back side of the substrate in addition to the semiconductor layer 300. In addition, part of the cathode contact 303, the cathode wiring 301, and the anode wiring 302, which are formed on the front side of the substrate and are connected to the semiconductor layer 300, are illustrated.

As illustrated in FIG. 9, the APD has a first semiconductor region 311 and a second semiconductor region 312 of the first conductivity type, and a PN junction is formed between the first semiconductor region 311 and the second semiconductor region 312.

By applying a predetermined reverse bias voltage to the first semiconductor region 311 and the second semiconductor region 312, electrons accelerated by the electric field cause avalanche multiplication. In addition, a fifth semiconductor region 315 (e.g., a P epilayer or N epilayer) with low impurity concentration is provided in a region on the back side of the second semiconductor region 312 in the semiconductor layer 300. Therefore, the configuration is such that the depletion layer expands toward the back side of the semiconductor layer 300 by applying a reverse bias voltage.

A seventh semiconductor region 317 is disposed so that at least part of the seventh semiconductor region 317 is brought into contact with an end portion of the first semiconductor region 311 in order to prevent edge breakdown, which occurs at a low voltage in the region when an intense electric field is applied to the end portion of the first semiconductor region 311. There are many dangling bonds, which are uncombined bonds of silicon, around the interface between the separation layer 324 and the semiconductor layer 300 and, thus, a dark current is generated via the crystal lattice defect level. To prevent the generation of the dark current, a third semiconductor region 313 of the second conductivity type is disposed in contact with the separation layer 324. For the same reason, a fourth semiconductor region of the second conductivity type is disposed on the back side of the semiconductor layer 300. In addition, by forming a pinning film 321 at the interface on the back side of the semiconductor layer 300, holes are induced on the side adjacent to the semiconductor layer 300 to prevent a dark current.

The cathode wiring 301 and the anode wiring 302 are disposed in the wiring layer on the front side of the semiconductor layer 300. The light incident on the semiconductor layer 300 is reflected into the semiconductor layer 300 by the above-described two types of wiring again and, thus, the incident light is efficiently photoelectrically converted.

FIG. 10 illustrates the pixel cross-sectional structure taken along line X-X in FIG. 8. FIG. 10 illustrates the cross section in a direction in which the microlens 323 is shared, and the light focusing position of microlens 323 is not the center position of each of the APDs, but a position between the APDs that share the microlens 323. To reflect the incident light by the anode wiring 302 in such a configuration, the width of the anode wiring 302 disposed between the APDs that share the microlens 323 is increased. That is, in one embodiment, to improve the sensitivity, a gap between the cathode wiring 301 and the anode wiring 302 that are separated to ensure the breakdown voltage be disposed at a distance from the light focusing position of the microlens 323.

As illustrated in FIG. 10, among the anode wirings 302, a width d1 corresponding to a side of the anode wiring 302 that does not share the microlens 323 and a width d2 corresponding to a side of the anode wiring 302 that shares the microlens 323 satisfy d1<d2. That is, in the first direction in which the APDs are lined up, the width of the first wiring (the anode wiring) disposed between the second wirings (the cathode wirings) of the APDs is greater than the width of the first wiring between a plurality of pixels. By employing a configuration that satisfies the above-described conditions, a photoelectric conversion apparatus having improved sensitivity can be provided in a pixel configuration in which a plurality of APDs share a microlens 323.

The pixel having one microlens 323 disposed above one APD illustrated on the left in FIGS. 8 to 10 may or may not be included in the photoelectric conversion apparatus. The effect described herein can be obtained if the photoelectric conversion apparatus includes a pixel having a configuration in which one microlens 323 is shared by the two APDs illustrated on the right of FIGS. 8 to 10.

### Second Embodiment

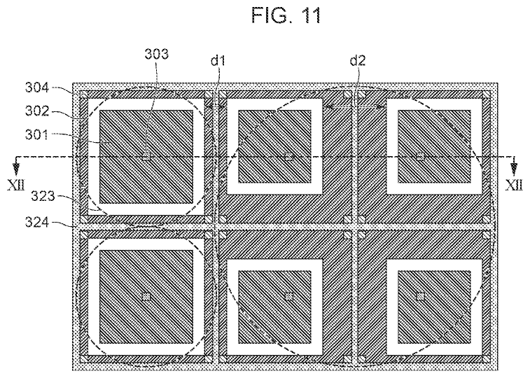

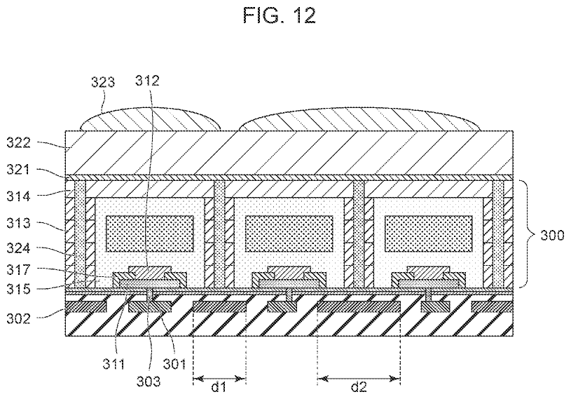

The second embodiment is described below with reference to FIGS. 11 and 12. According to the present embodiment, the number of APDs that share the microlens 323 differs from according to the first embodiment. FIG. 12 illustrates a cross section of the photoelectric conversion apparatus taken along line XII-XII of FIG. 11 which illustrates the planar structure of the photoelectric conversion apparatus.

Like FIG. 8, FIG. 11 does not necessarily illustrate only structures that are located in the same plane. For example, since the anode wiring 302 overlaps the separation layer 324 as viewed in plan view from the back side of the semiconductor layer 300, the separation layer 324 is illustrated in the foreground in FIG. 11. The anode wiring 302 is also continuously disposed at a region overlapping the separation layer 324 as viewed in plan view from the back side and has a mesh shaped configuration.

As illustrated in FIGS. 11 and 12, a microlens 323 is shared by four APDs arranged in two rows x two columns. That is, in the right pixel illustrated in FIG. 11, the microlens 323 is disposed so as to be common to a first avalanche photodiode, a second avalanche photodiode, a third avalanche photodiode, and a fourth avalanche photodiode. For each of the APDs, the width d1 of the anode wiring 302 on the side not adjacent to another APD that shares the microlens 323 and the width d2 of the anode wiring 302 on the side adjacent to another APD that shares the microlens 323 satisfy d1<d2.

Even in the case where the microlens 323 is shared by the APDs arranged in two rows x two columns, light is focused by the microlens 323 not at the center position of each of the APDs but at a position between the four APDs. Therefore, by setting the width of the cathode wiring 301 such that d1<d2 and placing the cathode wiring 301 in the orthogonal projection area near the center of the microlens, incident light can be reflected more efficiently, and the effect of sensitivity improvement can be obtained.

In addition, by configuring the four APDs to share the microlens 323, the direction of phase difference detection can be made different for different pixels. That is, according to the first embodiment, phase difference detection can be performed only in the first direction. However, according to the present embodiment, phase difference detection in a second direction orthogonal to the first direction can also be performed. The photoelectric conversion apparatus according to the present embodiment enables phase detection in more directions than the photoelectric conversion apparatus according to the first embodiment and enables high-precision autofocusing for a larger number of objects.

### Third Embodiment

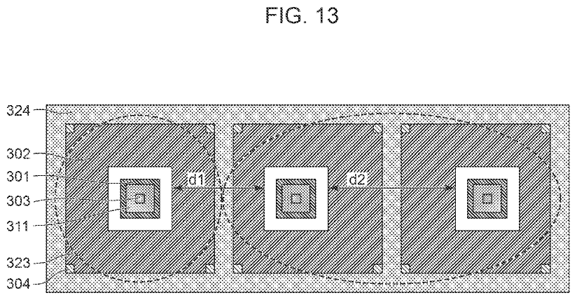

The third embodiment is described with reference to FIG. 13. Unlike the first and second embodiments, the present embodiment indicates the location of the first semiconductor region 311 as well as the location of the cathode wiring 301.

If there are a region where the cathode wiring 301 overlaps the avalanche region where the signal charge is multiplied and a region where the cathode wiring 301 does not overlap the avalanche region in plan view, the effect of the electric field from the cathode wiring 301 on the avalanche region is different in each region. This makes it difficult to form a uniform electric field within the avalanche region, which may worsen noise levels or reduce the sensitivity.

According to the present embodiment, for each of the APDs that share the microlens 323 illustrated in FIG. 13, the first semiconductor region 311 is disposed so as to be included in the cathode wiring 301 in plan view. That is, the entire surface of the first semiconductor region 311 is covered by the cathode wiring 301 in plan view. As a result, the cathode wiring 301 can be disposed at any location in the avalanche region, and the influence of the electric field from the cathode wiring 301 on the avalanche region can be aligned. Thus, noise deterioration and sensitivity reduction can be prevented.

Furthermore, by employing the arrangement in which the peripheral portions of the cathode wiring 301 are located at equal distance from the peripheral portions of the first semiconductor region 311, the influence of the cathode wiring 301 within the avalanche region can be aligned more. Therefore, as illustrated in FIG. 13, a structure in which the peripheral portion of the first semiconductor region 311 and the peripheral portion of the cathode wiring 301 are at equal distance from each other is used. In other words, a structure in which the shape of the first semiconductor region 311 and the shape of the cathode wiring 301 are similar in plan view is used. According to the present embodiment, as illustrated in FIG. 13, the sensitivity improvement effect can also be obtained by satisfying d1<d2 for the width of the cathode wiring 301.

### Fourth Embodiment

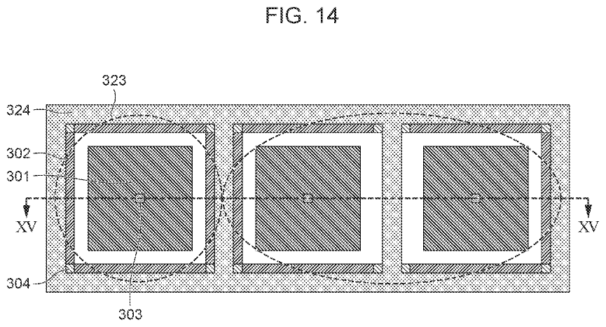

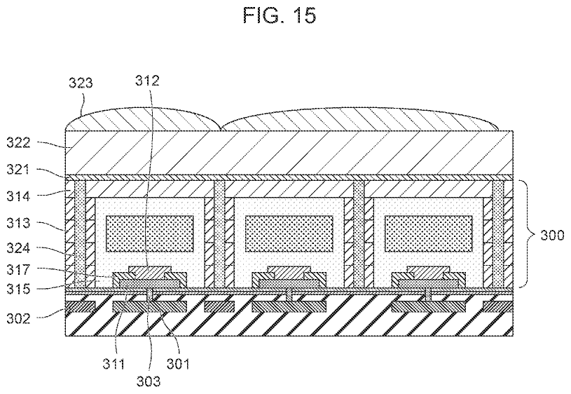

The present embodiment is described with reference to FIGS. 14 and 15. According to the present embodiment, the location of the anode wiring 302 is different from according to the first to third embodiments.

The photoelectric conversion apparatuses described in the first to third embodiments are intended to improve the sensitivity through a suitable reflective metal structure of pixels in which a plurality of APDs share a microlens 323. In addition, the photoelectric conversion apparatus according to the present embodiment is intended to reduce crosstalk between pixels that share the microlens 323. This is because there is a concern that crosstalk may occur between APDs due to reflected light when the structure that improves sensitivity by providing a reflective metal structure on the front side of the semiconductor layer 300 and reflecting light is applied to a pixel including a plurality of APDs that share a microlens 323.

The configuration according to the present embodiment is described with reference to FIG. 14. As illustrated in FIG. 14, a plurality of APDs share the microlens 323, and an anode wiring 302 is not disposed between the APDs of pixels that share the microlens 323. Like FIGS. 8 and 11, FIG. 14 does not necessarily illustrate only structures that are located in the same plane. For example, because the anode wiring 302 overlaps the separation layer 324 when viewed in plan view from the back side of the semiconductor layer 300, the separation layer 324 is illustrated in the foreground in FIG. 14. The anode wiring 302 is also continuously disposed at a region overlapping the separation layer 324 when viewed in plan view from the back side and has a mesh shaped configuration.

FIG. 15 illustrates the cross-sectional structure of the photoelectric conversion apparatus taken along line XV-XV in FIG. 14 which illustrates the planar structure of the photoelectric conversion apparatus. The anode wiring 302 is provided between a pixel that do not share a microlens 323 and a pixel that shares a microlens 323. However, no anode wiring 302 is provided between APDs of pixels that share the microlens 323.

In such a configuration, incident light is not reflected by the anode wiring 302 and penetrates into the wiring layer. This reduces the incidence of light reflected by the anode wiring 302 on the APDs that share the microlens 323 and, thus, reduces crosstalk.

### Fifth Embodiment

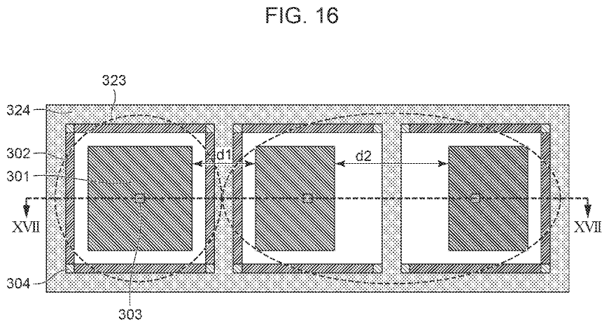

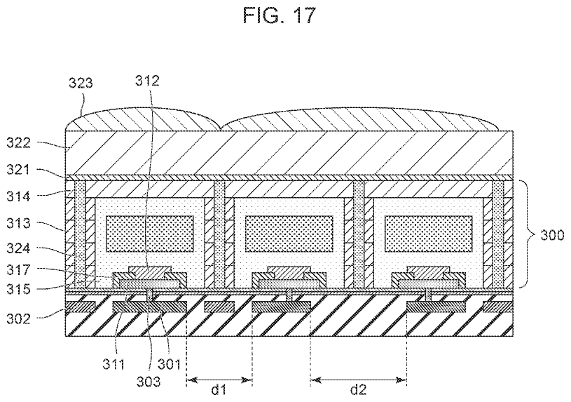

The differences between the present embodiment and the fourth embodiment are mainly described below with reference to FIG. 16 and FIG. 17.

The present embodiment is also intended to reduce crosstalk between APDs that share a microlens 323, and the location of the cathode wiring 301 is different from according to the fourth embodiment.

The locations of the anode wiring 302 and the cathode wiring 301 in a photoelectric conversion apparatus according to the present embodiment are illustrated in FIG. 16. Like the photoelectric conversion apparatus according to the fourth embodiment, the anode wiring 302 is not provided between APDs of pixels that share a microlens 323. Furthermore, the distance d2 between the cathode wirings 301 of APDs that share the microlens 323 and the distance d1 between the cathode wirings 301 between APDs that do not share the microlens 323 satisfy d1<d2. Like FIGS. 8, 11, and 14, FIG. 16 does not necessarily illustrate only structures that are located in the same plane.

FIG. 17 illustrates the cross-sectional structure taken along line XVII-XVII in FIG. 16 which illustrates the planar structure of the photoelectric conversion apparatus. The cathode wiring 301 disposed in the wiring layer is eccentrically formed in a direction away from the pixel that shares the microlens 323. That is, the center of gravity of the cathode wiring 301 is farther from the side of one APD facing the other APD than the center of the one APD. In other words, the distance from a first side of the cathode wiring to the side of the APD facing the other APD is greater than the distance from a second side opposite the first side of the cathode wiring to the side of the anode wiring facing the second side of the cathode wiring. The configuration increases the components of the incident light that is focused between the APDs sharing the microlens 323 and that penetrates into the wiring layer, as compared with the configuration described in the fourth embodiment. Therefore, crosstalk between pixels that share the microlens 323 caused by reflection from the anode wiring 302 can be further reduced.

### Sixth Embodiment

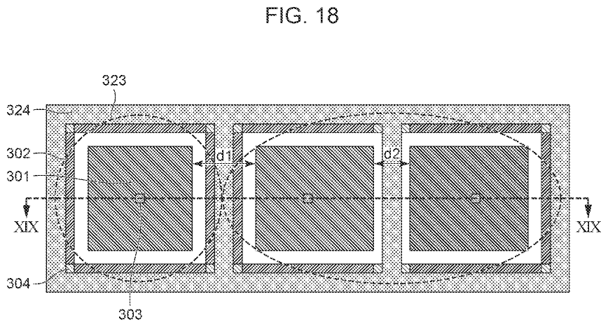

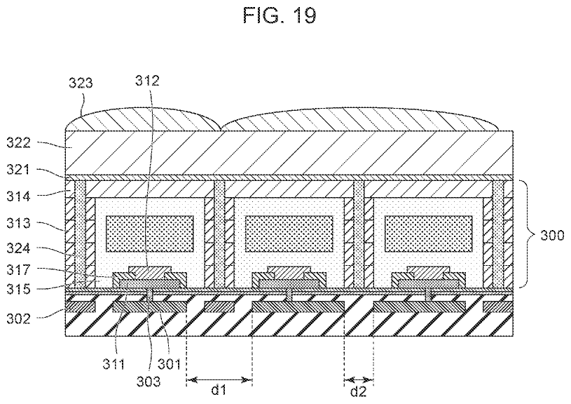

The present embodiment is described with reference to FIGS. 18 and 19. The present embodiment is also intended to reduce crosstalk between APDs that share a microlens 323, and the location of the cathode wiring 301 is different from according to the fourth and fifth embodiments.

The locations of the anode wiring 302 and the cathode wiring 301 in the photoelectric conversion apparatus according to the present embodiment are illustrated in FIG. 18. Like the photoelectric conversion apparatus according to the fourth embodiment, the anode wiring 302 is not provided between APDs of pixels that share the microlens 323. Furthermore, the distance d2 between the cathode wirings 301 of APDs that share the microlens 323 and the distance d1 between the cathode wirings 301 between APDs that do not share the microlens 323 satisfy d1>d2. Like FIGS. 8, 11, and 14, FIG. 18 does not necessarily illustrate only structures that are located in the same plane.

FIG. 19 illustrates the cross-sectional structure taken along line XIX-XIX in FIG. 18 which illustrates the planar structure of the photoelectric conversion apparatus. The cathode wiring 301 disposed in the wiring layer is eccentrically formed toward the pixel that shares the microlens 323. The configuration allows incident light focused between APDs that share the microlens 323 to be more easily reflected than in the fourth and fifth embodiments. According to the present configuration, crosstalk between APDs that share the microlens 323 caused by reflection from the anode wiring 302 is reduced and, in addition, the sensitivity improvement effect of the cathode wiring 301 can be obtained.

### Seventh Embodiment

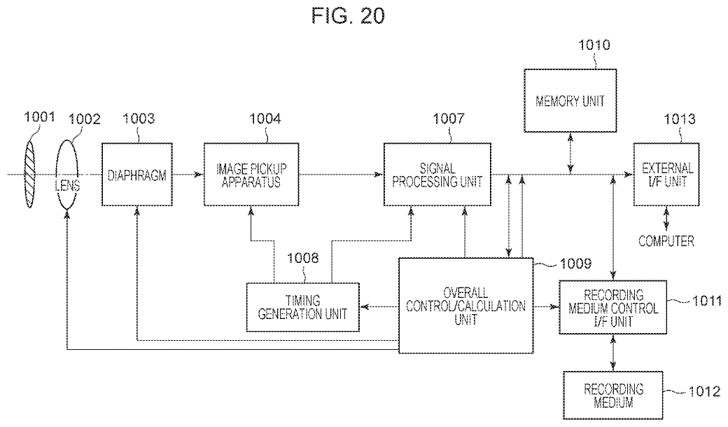

A photoelectric conversion system according to the present embodiment is described below with reference to FIG. 20. FIG. 20 is a block diagram of a schematic configuration of the photoelectric conversion system according to the present embodiment.

The photoelectric conversion apparatus described in each of the first to sixth embodiments can be applied to a variety of photoelectric conversion systems. Examples of an applicable photoelectric conversion system include a digital still camera, a digital camcorder, a surveillance camera, a copying machine, a facsimile, a mobile phone, on-vehicle camera, and an observation satellite. In addition, a camera module including an optical system, such as a lens, and an image pickup apparatus is included in the photoelectric conversion systems. FIG. 20 is a block diagram of a digital still camera as an example of the photoelectric conversion system.

The photoelectric conversion system illustrated in FIG. 20 includes an image pickup apparatus 1004 that is an example of a photoelectric conversion apparatus and a lens 1002 that forms an optical image of an object on the image pickup apparatus 1004. The photoelectric conversion system further includes a diaphragm 1003 for controlling the amount of light passing through the lens 1002 and a barrier 1001 for protecting the lens 1002. The lens 1002 and the diaphragm 1003 form an optical system for collecting light onto the image pickup apparatus 1004. The image pickup apparatus 1004 is the photoelectric conversion apparatus according to any one of the above-described embodiments. The image pickup apparatus 1004 converts an optical image formed by the lens 1002 into an electrical signal. The photoelectric conversion system further includes a signal processing unit 1007 that serves as an image generation unit that generates an image by processing an output signal output from the image pickup apparatus 1004. The signal processing unit 1007 performs various corrections and compressions as necessary and outputs image data. The signal processing unit 1007 may be formed in a semiconductor substrate having the image pickup apparatus 1004 provided therein or may be formed in a semiconductor substrate other than the semiconductor substrate having the image pickup apparatus 1004 therein.

The photoelectric conversion system further includes a memory unit 1010 for temporarily storing image data and an external interface unit (external I/F unit) 1013 for communicating with an external computer or the like. Still furthermore, the photoelectric conversion system includes a recording medium 1012, such as a semiconductor memory, for recording and reading image data therein and therefrom, and a recording medium control interface unit (recording medium control I/F unit) 1011 for recording or reading data in and from the recording medium 1012. The recording medium 1012 may be built in the photoelectric conversion system or may be removable.

Furthermore, the photoelectric conversion system includes an overall control/calculation unit 1009 that performs control of various calculations and overall control of the digital still camera and a timing generation unit 1008 that outputs various timing signals to the image pickup apparatus 1004 and the signal processing unit 1007. The timing signal and the like may be input from the outside, and the photoelectric conversion system can include at least the image pickup apparatus 1004 and the signal processing unit 1007 that processes the output signal output from the image pickup apparatus 1004.

The image pickup apparatus 1004 outputs an image pickup signal to the signal processing unit 1007. The signal processing unit 1007 performs predetermined signal processing on the image pickup signal output from the image pickup apparatus 1004 and outputs image data. The signal processing unit 1007 generates an image using the image pickup signal.

As described above, according to the present embodiment, a photoelectric conversion system that employs the photoelectric conversion apparatus (the image pickup apparatus) of any one of the above-described embodiments can be achieved.

### Eighth Embodiment

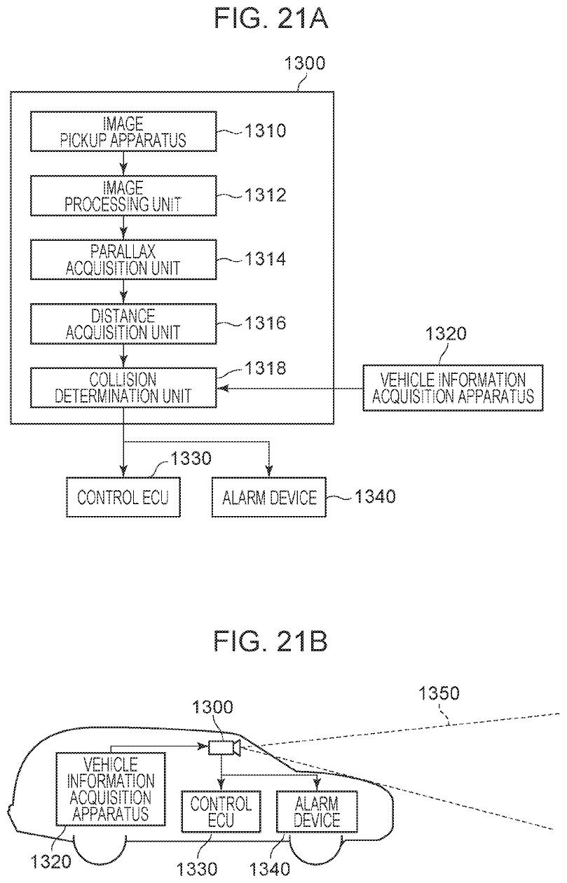

A photoelectric conversion system and a mobile object according to the present embodiment are described below with reference to FIGS. 21A and 21B. FIGS. 21A and 21B are diagrams illustrating the configurations of the photoelectric conversion system and the mobile object according to the present embodiment.

FIG. 21A illustrates an example of the photoelectric conversion system for an on-vehicle camera. A photoelectric conversion system 1300 includes an image pickup apparatus 1310. The image pickup apparatus 1310 is the photoelectric conversion apparatus described in any one of the above-described embodiments. The photoelectric conversion system 1300 includes an image processing unit 1312 that performs image processing on a plurality of image data acquired by the image pickup apparatus 1310 and a parallax acquisition unit 1314 that calculates a parallax (the phase difference of a parallax image) from the plurality of image data acquired by the photoelectric conversion system 1300. Furthermore, the photoelectric conversion system 1300 includes a distance acquisition unit 1316 that calculates the distance to a physical object on the basis of the calculated parallax and a collision determination unit 1318 that determines the collision probability on the basis of the calculated distance. The parallax acquisition unit 1314 and the distance acquisition unit 1316 are examples of distance information acquisition units for acquiring information regarding the distance to the physical object. That is, the distance information is information related to a parallax, a defocus amount, the distance to the physical object, and the like. The collision determination unit 1318 may use any one of these pieces of distance information to determine the collision probability. The distance information acquisition unit may be implemented by dedicatedly designed hardware or may be implemented by a software module.

Alternatively, the distance information acquisition unit may be implemented by a field programmable gate array (FPGA), an application specific integrated circuit (ASIC), or combinations thereof.

The photoelectric conversion system 1300 is connected to a vehicle information acquisition apparatus 1320. Thus, the photoelectric conversion system 1300 can acquire vehicle information, such as a vehicle speed, a yaw rate, and a steering angle. In addition, the photoelectric conversion system 1300 is connected to a control ECU 1330 which is a control unit that outputs a control signal for generating a braking force to the vehicle on the basis of the determination result of the collision determination unit 1318. Furthermore, the photoelectric conversion system 1300 is connected to an alarm device 1340 that emits an alarm to a driver on the basis of the determination result of the collision determination unit 1318. For example, if the collision determination unit 1318 determines that the collision probability is high, the control ECU 1330 performs vehicle control to avoid collisions or reduce damage by braking, releasing the accelerator pedal, or reducing the engine output. The alarm device 1340 emits an alarm to a user by, for example, sounding the alarm, displaying alarm information on a screen of a car navigation system, or vibrating a seat belt or steering wheel.

According to the present embodiment, the photoelectric conversion system 1300 captures the image of the surroundings of the vehicle, for example, the front view or rear view of the vehicle. FIG. 21B illustrates a photoelectric conversion system for capturing the image of the front view of the vehicle (an image capture range 1350). The vehicle information acquisition apparatus 1320 sends an instruction to the photoelectric conversion system 1300 or the image pickup apparatus 1310. Such a configuration can improve the accuracy of distance measurement.

While an example of performing control so as not to collide with another vehicle has been described, the configuration can also be applied to control of self-driving vehicles to follow another vehicle or control of self-driving vehicles to keep the lane. Furthermore, the photoelectric conversion system can be applied not only to a vehicle, but also to a mobile object (a moving apparatus), such as a boat, an aircraft, or an industrial robot. Still furthermore, the photoelectric conversion system can be applied not only to a mobile object but also to equipment that uses object recognition over a wide area, such as an intelligent transportation system (ITS).

### Ninth Embodiment

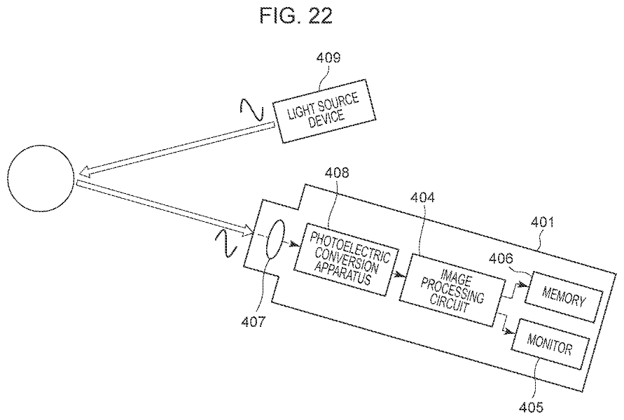

A photoelectric conversion system according to the present embodiment is described with reference to FIG. 22. FIG. 22 is a block diagram of a configuration example of a range image sensor, which is the photoelectric conversion system according to the present embodiment.

As illustrated in FIG. 22, a range image sensor 401 includes an optical system 407, a photoelectric conversion apparatus 408, an image processing circuit 404, a monitor 405, and a memory 406. The range image sensor 401 receives light (modulated light or pulsed light) projected from a light source device 409 toward an object and reflected by the surface of the object and, thus, can obtain a range image in accordance with the distance to the object.

The optical system 407 includes one or more lenses. The optical system 407 guides image light (incident light) from the object to the photoelectric conversion apparatus 408 and forms an image on the light receiving surface (a sensor unit) of the photoelectric conversion apparatus 408.

As the photoelectric conversion apparatus 408, the photoelectric conversion apparatus of any one of the embodiments described above is applied, and a distance signal indicating the distance obtained from the received light signal output from the photoelectric conversion apparatus 408 is supplied to the image processing circuit 404.

The image processing circuit 404 performs image processing to construct a range image based on the distance signal supplied from the photoelectric conversion apparatus 408. The range image (image data) obtained through the image processing is supplied to the monitor 405 and is displayed. In addition, the range image is supplied to the memory 406 and is stored (recorded).

In the range image sensor 401 configured in this way, by applying the above-described photoelectric conversion apparatus, it is possible to obtain, for example, a more accurate range image in accordance with improvement of the characteristics of the pixels.

### Tenth Embodiment

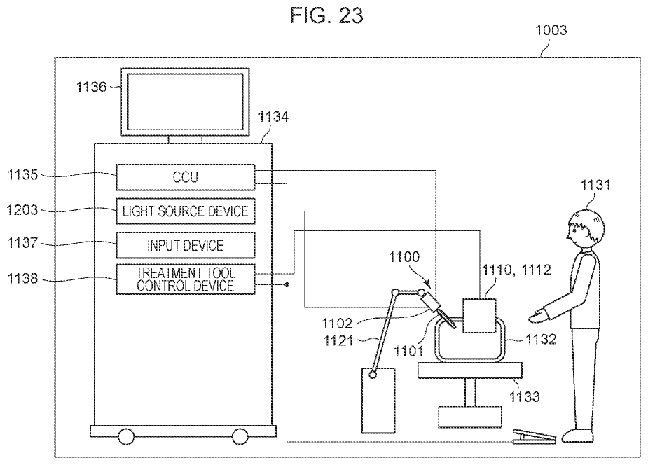

A photoelectric conversion system according to the present embodiment is described below with reference to FIG. 23. FIG. 23 illustrates an example of a schematic configuration of an endoscopic surgery system, which is the photoelectric conversion system according to the present embodiment.

FIG. 23 illustrates how an operator (a medical doctor) 1131 uses an endoscopic surgery system 1150 to perform surgery on a patient 1132 lying on a patient bed 1133. As illustrated in FIG. 23, the endoscopic surgery system 1150 includes an endoscope 1100, a surgical tool 1110, and a cart 1134 having a variety of devices for endoscopic surgery mounted therein.

The endoscope 1100 is composed of a lens barrel 1101, a predetermined length of the front end of which is to be inserted into the body cavity of the patient 1132, and a camera head 1102, which is connected to the base end of the lens barrel 1101. In the example of FIG. 23, the endoscope 1100 is illustrated that is configured as a so-called rigid scope having the lens barrel 1101 that is rigid. However, the endoscope 1100 may be configured as a so-called flexible scope having a lens barrel that is flexible.

An opening having an objective lens fitted thereinto is provided at the front end of the lens barrel 1101. A light source device 1203 is connected to the endoscope 1100, and light generated by the light source device 1203 is guided to the front end of the lens barrel 1101 by a light guide extending inside the lens barrel 1101. The light is emitted to an observation object in the body cavity of the patient 1132 through the objective lens. The endoscope 1100 may be a straight-viewing endoscope, an oblique-viewing endoscope, or a side-viewing endoscope.

An optical system and a photoelectric conversion apparatus are provided inside the camera head 1102, and the reflected light (observation light) from the observation object is focused on the photoelectric conversion apparatus by the optical system. The photoelectric conversion apparatus photoelectrically converts the observation light to generate an electrical signal corresponding to the observation light. That is, an image signal corresponding to the observation image is generated. As the photoelectric conversion apparatus, the photoelectric conversion apparatus described in any one of the above embodiments can be used. The image signal is transmitted to a camera control unit (CCU) 1135 in the form of RAW data.

The CCU 1135 includes a central processing unit (CPU), a graphics processing unit (GPU), and the like. The CCU 1135 comprehensively controls the operations performed by the endoscope 1100 and a display device 1136. Furthermore, the CCU 1135 receives an image signal from the camera head 1102 and performs various image processing, such as development processing (demosaicing), for displaying an image based on the image signal.

Under the control of the CCU 1135, the display device 1136 displays an image based on the image signal subjected to image processing performed by the CCU 1135.

The light source device 1203 includes a light source, such as a light emitting diode (LED), and supplies the endoscope 1100 with irradiation light for capturing the image of a surgical site or the like.

An input device 1137 is an input interface to the endoscopic surgery system 1150. A user can input a variety of information and instructions to the endoscopic surgery system 1150 via the input device 1137.

A treatment tool control device 1138 controls driving of an energy treatment tool 1112 for tissue cauterization, incision, blood vessel sealing, or the like.

The light source device 1203 that supplies irradiation light to the endoscope 1100 when the image of a surgical site is captured can include, for example, a white light source, such as an LED, a laser light source, or combinations thereof. When the white light source is configured by a combination of R, G, and B laser light sources, the output intensity and output timing of each of the colors (each of the wavelengths) can be controlled with high accuracy. Thus, white balance of a captured image can be adjusted in the light source device 1203. In this case, the observation target is irradiated with laser light from each of the R, G, and B laser light sources in a time-division manner, and driving of an image pickup element of the camera head 1102 is controlled in synchronization with the irradiation timing. In this way, an image corresponding to each of the RGB colors can be captured in a time-division manner. According to the technique, a color image can be obtained without providing a color filter on the image pickup element.

In addition, the driving of the light source device 1203 may be controlled such that the intensity of the output light is changed at predetermined time intervals. A high dynamic range without so-called crushed shadows and blown out highlights can be generated by controlling the driving of the image pickup elements of the camera head 1102 in synchronization with the timing of the change in the intensity of the light, acquiring images in a time-division manner, and combining the images.

In addition, the light source device 1203 may be configured so as to be able to supply light in a predetermined wavelength band corresponding to special light observation. In special light observation, the wavelength dependency of light absorption by a body tissue is used, for example. More specifically, a high contrast image of a predetermined tissue, such as a blood vessel on the surface of the mucous membrane, is captured by irradiating the tissue with light in a narrower band than the irradiation light used during normal observation (that is, white light).

Alternatively, in special light observation, fluorescence observation may be performed in which an image is captured using fluorescence generated by irradiation with excitation light. In fluorescence observation, a body tissue is irradiated with excitation light, and fluorescence from the body tissue can be observed. Alternatively, a reagent, such as indocyanine green (ICG), is locally injected into the body tissue, and the body tissue is irradiated with excitation light corresponding to the fluorescence wavelength of the reagent. Thus, a fluorescent image can be obtained. The light source device 1203 can be configured so as to supply narrowband light and/or excitation light corresponding to the special light observation.

### Eleventh Embodiment

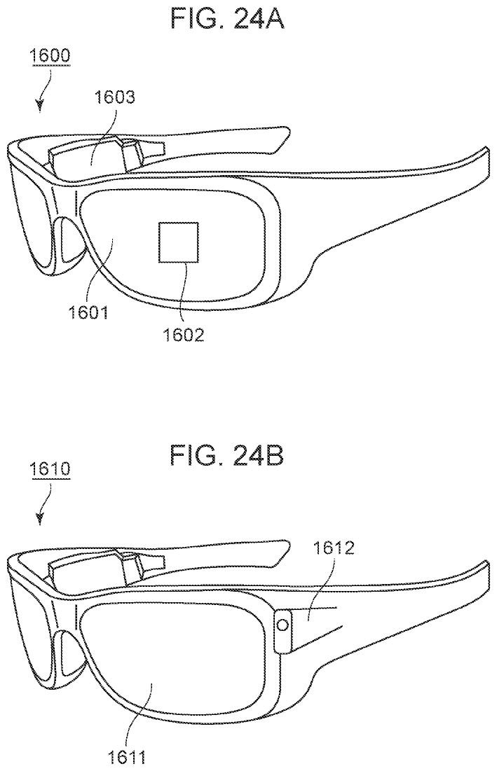

A photoelectric conversion system according to the present embodiment is described below with reference to FIGS. 24A and 24B. FIG. 24A illustrates glasses 1600 (smart glasses), which are the photoelectric conversion system according to the present embodiment. The glasses 1600 include a photoelectric conversion apparatus 1602. The photoelectric conversion apparatus 1602 is the photoelectric conversion apparatus described in any one of the above embodiments. A display device including a light emitting device, such as an OLED or an LED, may be provided on the rear surface side of a lens 1601. One or more photoelectric conversion apparatuses 1602 may be provided. Furthermore, a plurality of types of photoelectric conversion apparatuses may be combined and used. The mounting location of the photoelectric conversion apparatus 1602 is not limited to that illustrated in FIG. 24A.

The glasses 1600 further include a control device 1603. The control device 1603 functions as a power source that supplies electric power to the photoelectric conversion apparatus 1602 and the display device. In addition, the control device 1603 controls the operations performed by the photoelectric conversion apparatus 1602 and the display device. The lens 1601 has an optical system formed therein to focus light onto the photoelectric conversion apparatus 1602.

FIG. 24B illustrates glasses 1610 (smart glasses) according to an application example. The glasses 1610 include a control device 1612. The control device 1612 includes a photoelectric conversion apparatus corresponding to the photoelectric conversion apparatus 1602 and a display device. A lens 1611 includes, formed therein, the photoelectric conversion apparatus in the control device 1612 and an optical system for projecting light emitted from the display device. An image is projected to the lens 1611. The control device 1612 functions as a power source that supplies electric power to the photoelectric conversion apparatus and the display device and controls the operations performed by the photoelectric conversion apparatus and the display device. The control device may include a line-of-sight detection unit that detects the line of sight of a wearer. Infrared light may be used for line-of-sight detection. An infrared light emitting unit emits infrared light to the eyeballs of a user who is gazing at the display image. An image pickup unit including a light receiving element detects reflected light of the emitted infrared light from the eyeball and, thus, a captured image of the eyeball can be obtained. To reduce deterioration in image quality, a reduction unit is provided to reduce light from the infrared light emitting unit to a display unit in plan view.

The user's line of sight to the displayed image is detected from the captured infrared light images of the eyeball. Any known technique can be applied to line-of-sight detection using captured images of eyeballs. As an example, an eye gaze detection technique can be applied that is based on a Purkinje image obtained using reflection of irradiation light on the cornea.

More specifically, line-of-sight detection processing is performed on the basis of the pupillary-corneal reflection technique. The user's line of sight is detected by calculating a line of sight vector representing the orientation (the rotational angle) of the eyeball on the basis of the pupil image and the Purkinje image included in the captured eyeball image by using the pupillary-corneal reflection technique.

The display device according to the present embodiment may include a photoelectric conversion apparatus including a light receiving element and may control the display image of the display device on the basis of the user's line-of-sight information obtained from the photoelectric conversion apparatus.

More specifically, the display device determines a first field of view region that the user gazes at and a second field of view region other than the first field of view region on the basis of the line-of-sight information. The first field of view region and the second field of view region may be determined by a control unit of the display device. Alternatively, a first field of view region and a second field of view region determined by an external control device may be received. In the display area of the display device, the display resolution of the first field of view region may be controlled to be higher than the display resolution of the second field of view region. That is, the resolution of the second field of view region may be set to lower than that of the first field of view region.

Furthermore, the display area may have a first display area and a second display area different from the first display area, and a higher priority one of the first display area and the second display area may be determined on the basis of the line of sight information. The first field of view region and the second field of view region may be determined by the control unit of the display device. Alternatively, a first field of view region and a second field of view region determined by an external control device may be received. The resolution of a high priority area may be set higher than the resolution of an area other than the high priority area. That is, the resolution of a relatively low priority area may be decreased.

Artificial intelligence (AI) may be used to determine the first field of view region and a high priority area. AI model may be a model configured to estimate the angle of the line of sight and the distance to an object in the line of sight from the eyeball image by using, as training data, eyeball images and the directions in which the eyeballs in the images are actually looking. The AI program may be stored in the display device, the photoelectric conversion apparatus, or an external device. When stored in the external device, the AI program is transmitted to the display device via communication.

In the case of display control based on visual recognition detection, the display control can be applied to smart glasses that further include a photoelectric conversion apparatus that captures the image of the outside. The smart glasses can display captured external information in real time.

### Modification

The present disclosure is not limited to the above embodiments, and various modifications can be made. For example, an example in which part of the configuration of any one of the embodiments is added to another embodiment and an example in which part of the configuration of any one of the embodiments is replaced by part of another embodiment are also included in embodiments of the present disclosure.

In addition, the photoelectric conversion systems according to the seventh embodiment and the eighth embodiment are examples of photoelectric conversion systems to which the photoelectric conversion apparatus can be applied, and a photoelectric conversion system to which the photoelectric conversion apparatus according to the present disclosure can be applied is not limited to the configurations illustrated in FIGS. 20 to 23 and FIGS. 24A and 24B. The same applies to the ToF system according to the ninth embodiment, the endoscope according to the tenth embodiment, and the smart glasses according to the eleventh embodiment.

It should be noted that the above-described embodiments merely illustrate specific examples for carrying out the present disclosure, and the technical scope of the present disclosure should not be construed to be limited by the embodiments. That is, the present disclosure can be carried out in various forms without departing from its technical concept or main features.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-051698 filed Mar. 28, 2023, which is hereby incorporated by reference herein in its entirety.

What is claimed is:

1. An apparatus comprising:
a plurality of pixels;
a layer having a first surface and a second surface opposite the first surface, wherein the layer includes a plurality of photodiodes; and
a wiring layer disposed on a first surface side, wherein the wiring layer includes first wiring and second wiring,
wherein each of the plurality of pixels includes
a first photodiode,
a second photodiode located adjacent to the first photodiode in a first direction, and
a microlens disposed on a second surface side so as to be common to the first photodiode and the second photodiode, and
wherein a width of the first wiring disposed between the second wiring of the first photodiode and the second wiring of the second photodiode is greater than a width of the first wiring disposed between the plurality of pixels in the first direction.

2. The apparatus according to claim 1, wherein the first wiring provides a voltage to one of terminals of the photodiode, and
the second wiring provides a voltage to the other terminal.

3. The apparatus according to claim 1, wherein the first photodiode includes a first region of a first conductivity type and a second region of a second conductivity type configured to form PN junction with the first region in this order from the first surface side, and
wherein the second wiring of the first photodiode overlaps the first region of the first photodiode in plan view.

4. The apparatus according to claim 3, wherein a shape of the first region of the first photodiode and a shape of the second wiring of the first photodiode are similar in plan view.

5. The apparatus according to claim 1, wherein each of the plurality of pixels includes a third photodiode and a fourth photodiode, and
wherein the third photodiode and the fourth photodiode and the first photodiode and the second photodiode share the microlens.

6. A system comprising:
the apparatus according to claim 1; and
a processing unit configured to generate an image by using a signal output from the apparatus.

7. A mobile object comprising:
the apparatus according to claim 1; and
a control unit configured to control movement of the mobile object by using a signal output from the apparatus.

8. An apparatus comprising:
a plurality of pixels;
a layer having a first surface and a second surface opposite the first surface, wherein the layer includes a plurality of photodiodes; and
a wiring layer disposed on a first surface side, wherein the wiring layer includes first wiring and second wiring,
wherein each of the plurality of pixels includes
a first photodiode,
a second photodiode located adjacent to the first photodiode in a first direction, and
a microlens disposed on a second surface side so as to be common to the first photodiode and the second photodiode, and
wherein the first wiring is not provided between the second wiring of the first photodiode and the second wiring of the second photodiode in the first direction.

9. The apparatus according to claim 8, wherein the first wiring provides a voltage to one of terminals of the photodiode, and
the second wiring provides a voltage to the other terminal.

10. The apparatus according to claim 8, wherein the first photodiode includes a first region of a first conductivity type and a second region of a second conductivity type that forms PN junction with the first region in this order from the first surface side, and
wherein the second wiring of the first photodiode overlaps the first region of the first photodiode in plan view.

11. The apparatus according to claim 10, wherein a shape of the first region of the first photodiode and a shape of the second wiring of the first photodiode are similar in plan view.

12. The apparatus according to claim 8, wherein a center of gravity of the second wiring of the first photodiode is farther from a side of the first photodiode facing the second photodiode than a center of the first photodiode.

13. The apparatus according to claim 12, wherein a distance between a first side of the second wiring and the side is greater than a distance between a second side opposite to the first side of the second wiring and the first wiring facing the second side.

14. The apparatus according to claim 8, wherein a center of gravity of the second wiring of the first photodiode is closer to a side of the first photodiode facing the second photodiode than a center of the first photodiode.

15. The apparatus according to claim 14, wherein a distance between a first side of the second wiring and the side is less than a sum of a distance between a second side opposite to the first side of the second wiring and the first wiring facing the second side and a width of the first wiring.

16. The apparatus according to claim 8, wherein each of the plurality of pixels includes a third photodiode and a fourth photodiode, and
wherein the third photodiode and the fourth photodiode and the first photodiode and the second photodiode share the microlens.

17. A system comprising:
the apparatus according to claim 8; and
a signal processing unit configured to generate an image by using a signal output from the apparatus.

18. A mobile object comprising:
the apparatus according to claim 8; and
a control unit configured to control movement of the mobile object by using a signal output from the apparatus.
